(19) United States
(12) Patent Application Publication
(10) Pub. No.: US 2007/0273562 A1
(43) Pub. Date: Nov. 29, 2007

(54) Key Arrangement For Portable Electronic Device

(76) Inventors: Gary Wingett, Hampshire (GB); Trevor Andrews, Hampshire (GB)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 10/584,381

(22) PCT Filed: Dec. 23, 2004
(86) PCT No.: PCT/EP04/14746

§ 371 Date: Apr. 11, 2007

(30) Foreign Application Priority Data
Dec. 29, 2003 (GB) 0330104.1

(51) Int. Cl. H03M 11/00

(52) U.S. Cl. 341/34

(57) ABSTRACT

A key arrangement (24) for a portable electronic device (20) comprising a substantially planar body and an input key (25) wherein the input key is attachable to the body and is operable for relative movement along the confronting surfaces of the body and the input key.

The invention relates to a key arrangement for use in a portable electronic device. In particular it relates to an input key, which is attached to a substantially planar body and is operable such that the body and the input key allow relative movement between the confronting surfaces.

A portable electronic device, for example, a radiotelephone normally comprises a display and a user interface, typically an alphanumeric keypad, comprising a plurality of push buffon keys organised in a 4×3 matrix with some additional keys for pre-defined functions such as ‘Call’ and ‘End Call’. A user may input information to the radiotelephone using the alphanumeric keypad and simultaneously display that information on the display. In addition to the 4×3 matrix a radiotelephone may comprise further navigational keys such as a scroll key or rotator key to supplement the standard alphanumeric keypad in order to allow the user to quickly scroll through menu options. Such arrangements are present on the Nokia 7110 cellular mobile handset and the Bang & Olufsen Beocom 6000 Cordless phone.

In each of these handsets the navigational keys are positioned between the display and the alphanumeric keypad; the navigational key and the alphanumeric keypads have separate mounting arrangements internally within the handset. For example the navigational key used in the Nokia 7110 and disclosed in EP0901262 outlines a substantially cylindrical key supported and mounted to the PCB (printed circuit board) by a plurality of mechanical components.

It is a desirable feature of a hand portable radiotelephone that the size be compact and suitable for storing in a users pocket when not required. The size of the radiotelephone is limited by the size of the display, alphanumeric keypad and any navigational keys. While the use of a navigational key may provide a user with a fast method of scrolling through menu options, the separate mounting arrangements required by the alphanumeric keypad and the navigational keys will increase the size of the radiotelephone when compared to a like product not comprising a navigational key.

FIG. 1 shows a prior art radiotelephone comprising a navigational key and an alphanumeric keypad on the operating facia. The navigational key and the alphanumeric keypad are mounted such that they protrude through the outer casing of the radiotelephone.

FIG. 2 illustrates how the navigational key and the alphanumeric keypad could be mounted to a PCB. The alphanumeric keypad is usually printed on a flexible mat with keys, which protrude from the surface of the mat. The flexible mat is placed on a dome sheet; the dome sheet is attached to the PCB by means of a series of clips. The flexible mat is located on top of the dome sheet by fixing pins or by the mating of the outer housing of the radiotelephone. The keys on the flexible mat are co-axially located with domes on the dome sheet so pressure exerted on the keys is transferred to the domes on the dome sheet, which become depressed when pressure is exerted on the keys. The dome creates an electrical contact with a conductive pad on the PCB, which closes an electrical circuit, which can be utilised by the radiotelephone to determine when a key has been depressed. The mounting structure for the navigational key is also shown and can be seen to be separate to the mounting arrangement of the alphanumeric keypad.

Having separate mounting arrangements occupies space on the PCB, which may not be utilised by other components and may also result in a product, which is not compact.

In accordance with the present invention there is provided a key arrangement for a portable electronic device comprising a substantially planar body for lying over a circuit board that carries electronic components and an input key wherein said input key is attachable to said body and is operable for relative movement along the confronting surfaces of said body and said input key.

In a preferred embodiment the body is a mat, preferably a keymat comprising a plurality of push button keys for pre-defined functions and the input key is a rotary key. The rotary key may be actuated in or between a plurality of positions.

An advantage of the present invention is that it allows fixed and moveable keys to be located on a single keymat structure, providing a key arrangement. An advantage of such an arrangement is that the overall size of the key arrangement in comparison with a separate keymat and navigational key will be smaller. A further advantage is that the number of mechanical parts may be reduced as the rotary key has become part of the key arrangement and does not need to be mounted separately to the portable electronic device nor does it have to be mounted to a pivotable support. The overall height of the present invention when compared to a pivot mounted rotary key or a scroll key would be reduced, as there is no need for a mounting structure. Furthermore actuation of the rotary key in a direction perpendicular to the PCB may be made in a similar arrangement to that of fixed push button keys.

### BRIEF DESCRIPTION OF THE DRAWINGS

FIG. 1 shows a prior art drawing of a radiotelephone having a navigational key and a plurality of push button keys;

FIG. 2 shows an internal view of the radiotelephone of FIG. 1 illustrating how the navigational key and keymat could be mounted inside the radiotelephone;

FIG. 3 shows a radiotelephone comprising a key arrangement according to the present invention;

FIG. 4 shows a key arrangement according to the present invention;

FIG. 5 shows an exploded view of FIG. 4 illustrating a rotary disc above the keymat structure, which is above a section of PCB;

FIG. 6 shows a cross sectional view of the key arrangement of FIG. 5;

FIG. 7 shows a further key arrangement according to the present invention comprising an annular rotary key;

FIG. 8 shows an exploded view of FIG. 7 illustrating the key arrangement above a section of PCB;

FIG. 9 shows a further key arrangement according to the present invention comprising a slide key.

### DETAILED DESCRIPTION OF THE PREFERRED EMBODIMENTS

Embodiments of the present invention will now be described, by way of example only, with reference to the accompanying drawings.

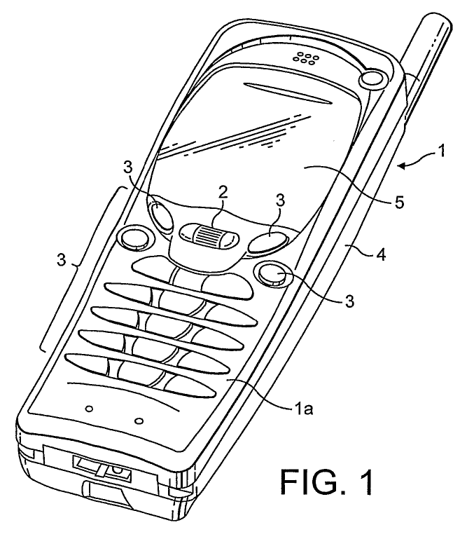

FIG. 1 illustrates a prior art drawing of a radiotelephone 1 that has a key arrangement comprising a navigational key 2 and a plurality of push button keys 3. The radiotelephone 1 also includes radio reception and transmission means (not shown) contained substantially within the casing 4 of the radiotelephone 1. Also illustrated is a display 5 which as well as the plurality of push button keys 3 and the navigational key 2 are positioned on the operating facia 1a of the radiotelephone 1 and protrude through the casing 4.

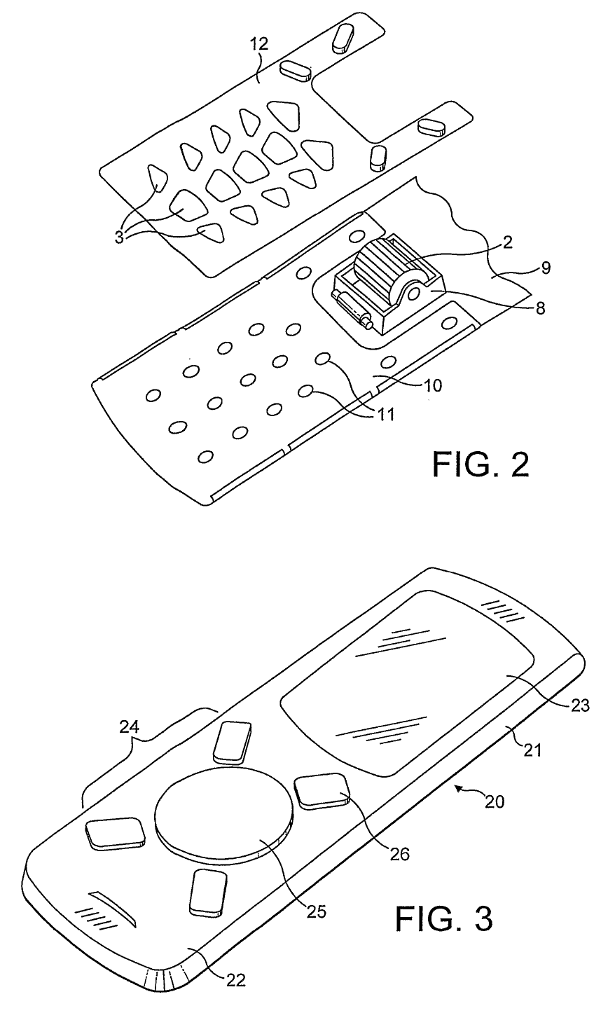

The radiotelephone of FIG. 1 is illustrated without the casing 4 in FIG. 2, which is a partially exploded view. The radiotelephone 1 comprises a PCB 9 used for mounting electronic circuitry (not shown); the navigational key 2 is illustrated in a mounting arrangement 8 attached to the PCB 9. A dome sheet 10 is also attached to the PCB 9; the dome sheet 10 comprises a plurality of domes 11 which are located coaxially with the push button keys 3. The keys are arranged on a flexible keymat 12, which is located on top of the dome sheet 10. The interaction of the plurality of keys 3 and the domes 11 in order to create an electrical response is appreciated by those skilled in the art.

Other navigational keys, such as a rotary key could be mounted on a pivotable support, which is mounted directly to the PCB 9.

An illustration of a radiotelephone comprising a key arrangement in accordance with the present invention is shown in FIG. 3. A radiotelephone 20 comprises a casing 21 which houses radio reception and transmission means (not shown) contained substantially within the casing 21. On the main operating facia 22 of the radiotelephone 20 is an LCD display 23 placed towards the upper end of the main operating facia 22 and a key arrangement 24, which protrudes through the casing 21 and is located towards the lower end of the main operating facia 22. The key arrangement 24 provides input means to the user. The key arrangement 24 comprises a planar body (not shown) upon which are a navigational key 25 and four push button keys 26.

The navigational key 25 is a rotary disc and is placed centrally on the planar body. The push button keys 26 are positioned around the navigational key at each corner of the planar body. The main axis of the push button keys corresponds generally with the axis joining opposing corners of the planar body. In an alternative arrangement the number of push button keys and the position of the navigational key may be determined by the design aesthetics of the radiotelephone 1 and is not limited to the exemplary arrangement of FIG. 3.

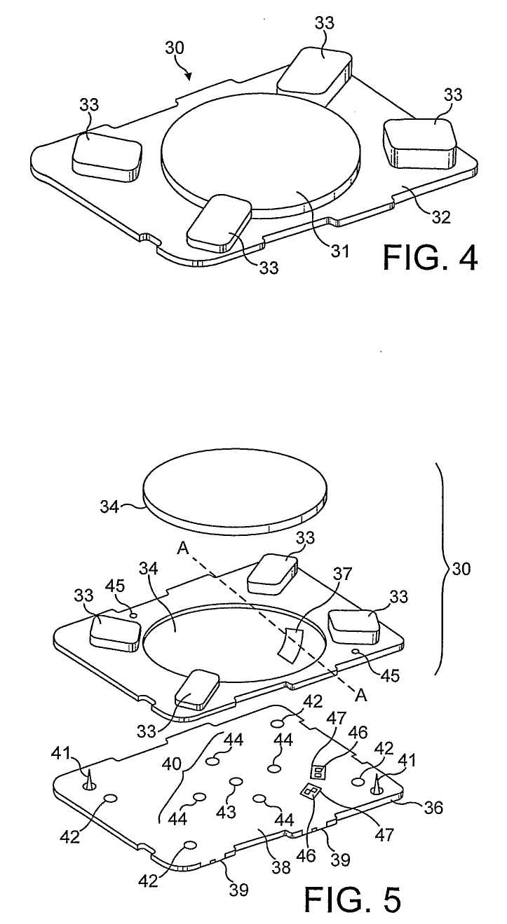

FIG. 4 illustrates an exemplary key arrangement 30 according to the present invention. The key arrangement 30 comprises an attachable input key 31 and a body 32; in a preferred embodiment the attachable input key 31 is a rotary disc and the body 32 is a keymat. The keymat 32 is substantially rectangular; in an alternative embodiment the keymat 32 may have other forms, for example square, elliptical or circular. The keymat 32 is substantially planar save for four push button keys 33 and a recessed area (not shown); the push button keys 33 are positioned at each corner of the keymat 32 and are orientated such that their major axis corresponds generally with the axis between opposing corners of the keymat 32. In an alternative arrangement (not shown) the push button keys 33 may be any shape, for example square, elliptical or circular and may be placed at different positions on the keymat 32 in keeping with the design aesthetics of a portable electronic device. The push button keys 33 are of a height such that they may protrude through the casing of a portable electronic device, as illustrated in FIG. 3, in order to provide an input means to the user.

The rotary disc 31 is cylindrical and locates within the recessed area of the keymat 32. The rotary disc 31 is attachable to the keymat 32 by tabs (not shown) located around the outer cylindrical surface of the rotary disc and or tabs (not shown) located around the inner cylindrical surface of the recessed area. The tabs are designed such that the rotary disc 31 is detachable from the keymat 32. The rotary disc 31 is mounted so that its axis of rotation is perpendicular to the operating facia of the keymat 32 and may be rotated in a clockwise or anti-clockwise direction. The height of the rotary disc 31 when located on the keymat 32 is similar in height to the push button keys 33 so that it may protrude through the casing of a radiotelephone, illustrated in FIG. 3.

A partially exploded view of the key arrangement 30 of FIG. 4 is illustrated in FIG. 5. Reference numerals 30-33 in FIG. 4 have the same corresponding reference numbers in FIG. 5. The key arrangement 30 is shown above a section of PCB 36 in order to illustrate the interaction between the key arrangement 30 and the PCB 36. The detachment of the rotary disc 31 from the keymat 32 reveals a recessed area 34 within which the rotary disc 31 is located. The recessed area 34 comprises an aperture 37, which allows the transmission of electromagnetic waves, preferably in the visible or infrared region of the electromagnetic spectrum.

A dome sheet 38 lies on a major surface of the PCB 36 and is attached to it by means of locating clips 39. The dome sheet 38 comprises a number of raised domes 40 which are co-axially located above conductive pads (not shown) present on the surface of the PCB 36. The keymat 32 lies on top of the dome sheet 38 such that it is in direct contact with the dome sheet 38. The keymat 32 is positioned so that the push button keys 33 and the rotary disc 31 are co-axially aligned with their corresponding raised domes 40. FIG. 5 illustrates that the push button keys 33 are each associated with a raised dome 42. In a preferred embodiment the rotary disc is associated with five raised domes 43,44. A centrally positioned raised dome 43 is located so that it is aligned co-axially with the centre of the rotary disc 31. The further four raised domes 44 are positioned around the centrally positioned raised dome 43 along a major and minor axis of the dome sheet 37 and located so as to coincide coaxially with a non-central portion of the rotary disc 31. In alternative embodiments more or less raised domes could be used beneath the rotary disc 31 to more or less accurately determine where the rotary disc 31 had been depressed in an axis perpendicular to the rotary disc 31. Support pins 41 which protrude from the PCB 36 and pass through locating holes 45 on the keymat 32 may locate the keymat 32. It will be appreciated by those skilled in the art that other locating means are available.

It is recognised by those skilled in the art that pressure exerted on the push button keys 33 or on the rotary disc 31 in a direction perpendicular to the keymat 31 is transferred to the corresponding raised domes 42,43 or 44 which become depressed so as to form an electrical contact with a conductive pad (not shown) on the surface of the PCB 36 so as to create an electrical response. The electrical response is used by the radiotelephone to determine when an input key 31,33 has been depressed.

The aperture 37 within the recessed area 34 permits the passing of electromagnetic waves from and to motion sensing circuitry 46, for example infrared sensors, which are mounted to the PCB 36 and placed coaxially with the aperture 37. They transmit electromagnetic waves through the aperture 37 to be reflected from the rear surface (the surface which faces the PCB 36) of the rotary disc 31 to the motion sensing circuitry 46. In this embodiment the rear surface of the rotary disc 31 may comprise electromagnetically reflective and absorbent areas. In an alternative embodiment a section of the keymat 32 in the absence of an aperture 37 (not shown) may be constructed from a material, which permits the passing of electromagnetic waves from and to the sensing circuitry 46. This solution may be preferable to inhibit water ingress from the outside of the radiotelephone casing to the PCB 36. In either embodiment electrical short circuits between the motion sensing circuitry 46 mounted on the PCB 36 and the dome sheet 38 are avoided by placing perforations 47 in the dome sheet 38 coincidental with the motion sensing circuitry 46.

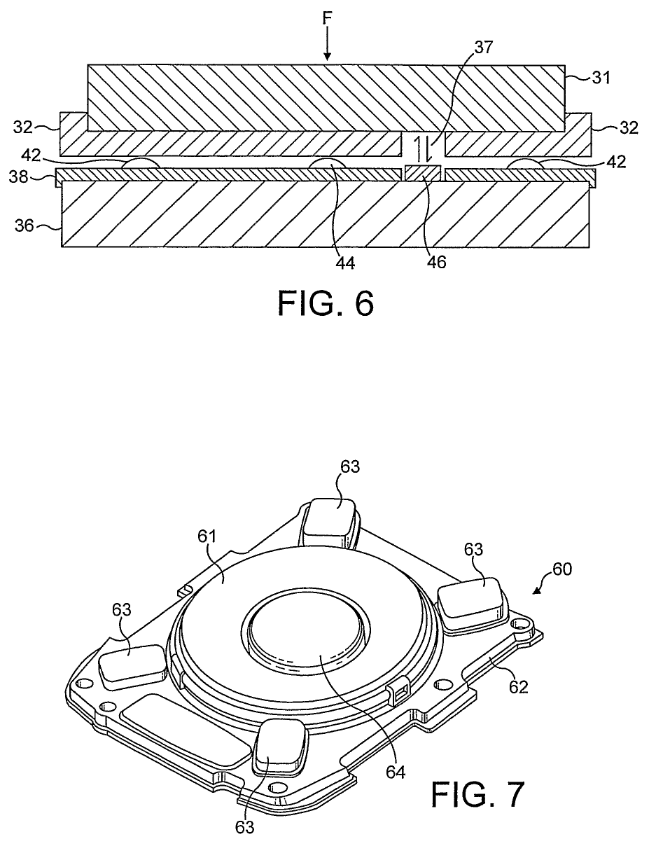

FIG. 6 illustrates a cross sectional view AA of FIG. 5 which shows how a force F exerted on the rotary disc 31 will be transferred to the raised dome 44. Additionally, the transmission of the electromagnetic waves between the motion sensing circuitry 46 and the rear surface (the surface which faces the PCB 36) of the rotary disc 31 via the aperture 37 is illustrated.

In further alternative embodiments the motion sensing circuitry 46 may be mechanical, magnetic or electromagnetic motion sensing circuitry. They need not be mounted on the PCB 36 but may be located on the keymat 32.

In this embodiment the touching confronting surfaces are the rear surface (the surface which faces the PCB 36) of the rotary disc 31 and the major facia (the surface which faces away from the PCB 36) of the recessed area 34 and or the outer cylindrical surface of the rotary disc 31 and the inner cylindrical surface of the recessed area 34.

The touching confronting surfaces of the keymat 32 and the rotary disc 31 are made from materials, i.e. low frictional coefficient, which allows movement. This allows a user to be able to exert a force on the rotary disc 31 with a single digit and movement between touching confronting surfaces is achieved. The frictional coefficient should not be so low as to allow rotational movement when the rotary key has no force exerted by a user on it. The keymat 32 may be constructed from a material such as silicon. Alternatively the keymat 32 may be constructed using co-moulded materials such as polycarbonate and silicon such that the touching confronting surface of the keymat 32 is formed from silicon, to provide flexibility and a low frictional co-efficient between the keymat 32 and the rotary disc 31. Other areas of the keymat 32 may use polycarbonate to provide some rigidity and strength to the keymat 32.

A further embodiment of the present invention is illustrated in FIG. 7. The key arrangement of FIG. 7 is the same as the key arrangement of FIG. 4 save for the rotary disc 31 being replaced by an annular rotary key 61. Figure references 30-33 of FIG. 4 have corresponding figure references 60-63 respectively. The keymat 62 has a circular key 64 positioned centrally to the keymat 62; in this embodiment the circular key 64 operates in the same way as the push button keys 33 described in FIG. 5. In a further embodiment the circular key 64 may operate in a similar way to a navigational key permitting a number of possible inputs; for example central depression of the circular key 64 may act as a ‘SELECT’ function. Depression of the circular key at the left or right hand side may result in a left or right scrolling function respectfully, while depression of the circular key at the top or bottom may result in a up or down scrolling function respectfully. The height of the circular key 64 is similar to the push button keys 63. The annular rotary key 61 is located around the circumference of the circular key 64 such that the outer cylindrical surface of the circular key 64 confronts the surface of the inner cylindrical surface of the annular rotary key 61. In this embodiment the touching confronting surfaces are either of the inner cylindrical surface of the annular rotary key 64 and the outer cylindrical surface of the circular key 65 and or the rear surface (the surface which faces towards the PCB) of the annular rotary key 61 and the surface (the surface which faces away from the PCB) of the keymat 62.

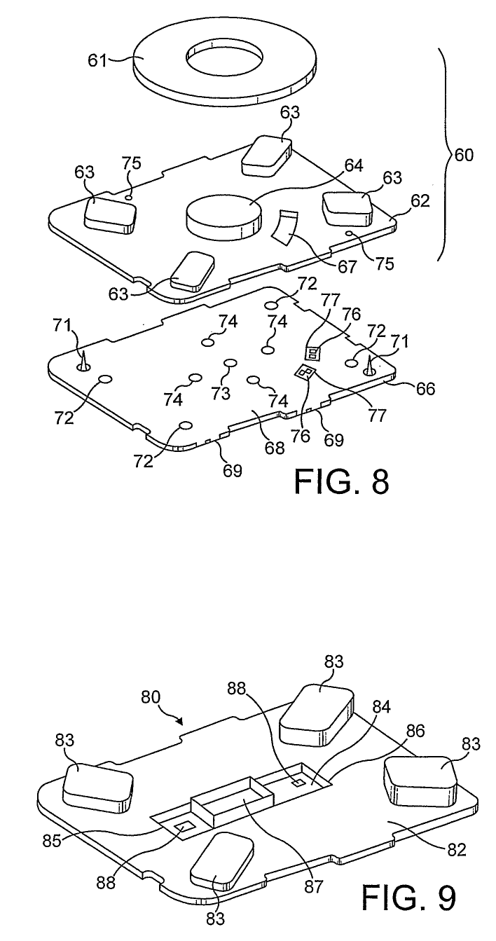

FIG. 8 illustrates an exploded view of FIG. 7; the reference numbers 30-47 of FIG. 5 have corresponding reference numbers 60-77 respectively. In this embodiment the recessed area 34 of FIG. 5 does not have an equivalent recessed area in FIG. 8. In this embodiment the rotary annular key 61 may clip onto the circular key 64. However, in an alternative embodiment (not shown) a recessed area could be used to locate the annular rotary key 61 in addition to the circular key 64. This would provide a further confronting surface, which could be touching.

A further key arrangement 80 is illustrated in FIG. 9; the reference numerals 32, 33 have corresponding reference numerals 82, 83 respectively. The key arrangement 80 is similar to the key arrangement 30 of FIG. 4 save for the absence of a rotary disc 31. The keymat 82 has a longitudinal recessed area 84 coincidental with the major axis of the keymat 82 and having a lower end 85 and an upper end 86 which are not coincidental with the upper edges of the keymat 82. The key arrangement 80 also comprises an attachable slideable rectangular key 87 which is located within the longitudinal recessed area 84 and may be attached by means of a tab (not shown) located on one or more of the confronting surfaces. The slideable key 87 protrudes from the longitudinal recessed area 84 to a height similar to the height of the keys 83 so that the slideable key 87 may protrude through the casing of a radiotelephone (not shown). The slideable key 87 is arranged so that it comprises at least one touching confronting surface with one of the surfaces of the longitudinal recessed area 84. In this embodiment there are three touching confronting surfaces, they are; the rear surface (surface which faces the PCB) of the slideable key 87 and the major surface of the recessed area 84; and the longitudinal sides of the slideable key 87 and the longitudinal sides of the recessed area 84. In alternative embodiments this key arrangement may have one or two touching confronting surfaces.

The touching confronting surfaces of the keymat 81 and the slideable key 87 are made from materials which allow movement in the same way as that outlined for the rotary disc 31 of FIG. 4. Movement of the slideable key 87 is along the major axis of the longitudinal recessed area 84 between the lower end 85 and upper end 86 of the longitudinal recessed area 84. Movement of the slideable key 87 in an axis perpendicular to the keymat 81 may also be allowed and any such movement may be detected by the use of raised domes as outlined in previous key arrangements. Longitudinal movement of the slideable key 87 may be determined by the use of apertures 88 and sensing circuitry e.g. infra-red sensors as outlined for the key arrangements 30 and 60 of FIGS. 5 and 8 respectively.

The skilled man will understand that other modifications can be made within the scope of the invention. For example, the rotary disc 31 of FIGS. 4 and 5 may have a smaller diameter than the recessed area 34 of the keymat 32 so as to allow movement in axes, which are parallel to the plane of the keymat 32. The keymats 32,62 and 82 may have a plurality of apertures and sensing circuitry to determine relative movement between the input keys 31,61 and 81 and the keymats 32,62 and 82 respectively.

The present invention includes any novel feature or combination of features disclosed herein either explicitly or any generalisation thereof irrespective of whether or not it relates to the claimed invention or mitigates any or all of the problems addressed.

What is claimed is:

1. An apparatus comprising:
a substantially planar body for lying over a circuit board that carries electronic components; and
an input key wherein said input key is attachable to said body and is operable for relative movement along confronting surfaces of said body and said input key.

2. The key arrangement according to claim 1 wherein the confronting surfaces touch.

3. The key arrangement according to claim 2 wherein the confronting surfaces annularly touch.

4. The key arrangement according to claim 1 wherein said relative movement is rotational.

5. The key arrangement according to claim 1 wherein said relative movement is translational.

6. The key arrangement according to claim 1 wherein said input key is actuable in an axis perpendicular to the plane of said substantially planar body.

7. The key arrangement according to claim 4 wherein said body comprises a substantially planar recessed area within which said input key is substantially located.

8. The key arrangement according to claim 6 wherein said body comprises a stanchion.

9. The key arrangement according to claim 8 wherein said stanchion is an actuable key.

10. The key arrangement according to claim 1 wherein said body comprises a plurality of actuable keys.

11. The key arrangement according to claim 1 wherein said input key is a rotary key.

12. The key arrangement according to claim 11 wherein said rotary key is an annular key.

13. The key arrangement according to claim 1 wherein said body is a flexible mat.

14. The key arrangement according to claim 1 wherein said input key is slideable.

15. The key arrangement according to claim 1 wherein said input key is detachable from said body.

16. The key arrangement according to claim 1 for a radiotelephone.

17. A radiotelephone including a key arrangement according to claim 1.

18. (canceled)

19. A method comprising:
laying a substantially planar body over a circuit board that carries electronic components and an input key, and
attaching said input key to said body so as to be operable for relative movement along confronting surfaces of said body and said input key.

20. The method of claim 19 wherein the confronting surfaces touch.

21. The method of claim 19 wherein the confronting surfaces annularly touch.

22. An apparatus comprising:
means for laying a substantially planar body over a circuit board that carries electronic components and an input key, and
means for attaching said input key to said body so as to be operable for relative movement along confronting surfaces of said body and said input key.

23. The apparatus of claim 22 wherein the confronting surfaces touch.
